(19) United States
(12) Patent Application Publication
(10) Pub. No.: US 2005/0022742 A1
(43) Pub. Date: Feb. 3, 2005

(54) Chemical vapor deposition processing equipment for use in fabricating a semiconductor device

(76) Inventors: Hyung-Sik Hong, Suwon-si (KR); Gyeong-Su Keum, Suwon-si (KR); Yong-Gab Kim, Suwon-si (KR); Chung-Hun Park, Suwon-si (KR); Do-In Bae, Changwon-si (KR); Seung-Ki Chae, Seoul (KR); Jung-Hun Cho, Suwon-si (KR)

Correspondence Address: LEE & STERBA, P.C.;Suite 2000, 1101 Wilson Boulevard, Arlington, VA, 22209, US

(21) Appl. No.: 10/900,150

(22) Filed: Jul. 28, 2004

(30) Foreign Application Priority Data
Jul. 29, 2003 (KR) 2003-52178

(51) Int. Cl. C23C 16/00

(52) U.S. Cl. 118/725

(57) ABSTRACT

Chemical vapor deposition (CVD) processing equipment for use in fabricating a semiconductor device requiring deposition of an insulation layer or a metal layer includes a chamber having an exhaust line in a lower central portion thereof, a heater block for supporting a wafer to be supplied in an interior of the chamber, the heater block having a heating plate in an interior thereof, a support shaft for supporting the heater block, and an electrical wire for providing an electrical connection to the heating plate. The support shaft extends through a bottom of the chamber. The electrical wire extends through the bottom of the chamber within the support shaft.

### BACKGROUND OF THE INVENTION

1. Field of the Invention

The present invention relates to fabrication of a semiconductor device. More particularly, the present invention relates to chemical vapor deposition (CVD) processing equipment for use in fabricating a semiconductor device, which requires a deposition of an insulation layer or a metal layer.

2. Description of the Related Art

A chemical vapor deposition (CVD) process, which is frequently performed during fabrication of a semiconductor device, deposits a desired material layer by supplying a gaseous raw material into a chamber having a wafer in a heated state therein. In the chamber, the gaseous raw material reacts to a surface of the heated wafer to form the desired material layer on the surface of the wafer.

FIGS. 1 and 2 illustrate a partial cut-away and sectional view, respectively, of a first conventional CVD processing equipment for use in a CVD process. FIG. 3 illustrates an enlarged view of a region “III” of FIG. 2 showing a connection of a heater block to an external power source.

Referring to FIGS. 1 and 2, a chamber 10 having a predetermined size includes a showerhead 12 for supplying a gaseous raw material to an interior of the chamber and an exhaust line 16 for guiding and exhausting the gaseous raw material supplied to the interior of the chamber 10. The showerhead 12 is installed on an interior upper portion of the chamber 10 and the exhaust line 16 is provided in a lower central portion of the chamber 10. A heater block 20, which has a flat surface, is centrally positioned in the interior of the chamber 10 and is equipped to support a wafer W contained in the interior of the chamber 10. The heater block 20 is supported by a bracket 14 fixed to an internal wall of the chamber 10 to maintain a gap between the heater block 20 and inner walls, i.e., sidewalls and a bottom wall, of the chamber 10.

A lift part 40 is provided on a side part of the heater block 20. The lift part 40 selectively raises and lowers the wafer W up from or down to an upper surface of the heater block 20, i.e. a platen 26. The lift part 40 includes a cylinder 46 supported from a bottom of the chamber 10, a lift pin 44 that is raised or lowered by the cylinder 46, and a wafer support 42 having a shape corresponding to a flute 26a formed on the platen 26. The wafer support 42 is supported by the lift pin 44.

The heater block 20 will now be described in more detail with reference to FIGS. 1 through 3. The heater block 20 includes a receptacle shaped body 22. The body 22 is supported by the bracket 14 installed on the internal sidewall of the chamber 10 so that a gap is maintained between the body 22 and the internal walls of the chamber 10. A gap retaining part 24 having a ring shape is positioned on an upper edge portion of the body 22. A platen 26 formed of a graphite material is positioned on an upper part of the gap retaining part 24 to contact a lower surface of the wafer W, thereby supporting the wafer W. The body 22, the gap retaining part 24 and the platen 26 are attached together by a general fastener 26b. In addition, a support body 28 formed of a quartz material is positioned on the body 22 between the body and the platen 26. A first heating plate 30 and a second heating plate 32, each having a flat surface, are positioned on an upper surface of the support body 28. An interior of the first and second heating plates is provided with a hot wire, i.e., a wire that is capable of generating heat when electricity flows therethrough.

In order to electrically connect an external power source to the first and second heating plates 30, 32, first terminal sockets 34a having a projected shape are formed on the support body 28 at positions corresponding to the first and second heating plates 30, 32. Portions of the first and second heating plates 30, 32 corresponding to the positions of the first terminal sockets 34a have a shape into which a corresponding first terminal socket 34a may be inserted to form an electrical connection between the first terminal socket 34a and either the first or second heating plate 30, 32 at a position C1. The first terminal socket 34a electrically connects to a first electrode rod 36a inserted into the support body 28 at a position C2. The first electrode rod 36a electrically connects to a second terminal socket 34b at a position C3. The second terminal socket 34b electrically connects to a second electrode rod 36b at a position C4. The second electrode rod 36b is connected to an external power source supply part (not shown). The second electrode rod 36b extends through the support body 28, a sidewall of the body 22, and exits through a sidewall of the chamber 10.

This first conventional equipment additionally includes a purge gas supply line 38 connected to the heater block 20. The purge gas supply line 38 prevents an influx of gaseous raw material into a space where the first and second heating plates 30, 32 are positioned by supplying a purge gas into the space. The purge gas supply line 38 extends from outside the chamber 10 through a sidewall of the chamber 10 and the body 22 of the heater block 20. A thermocouple 39 is installed on the heater block 20 to identify a temperature of the first and second heating plates 30, 32. The thermocouple 39 is inserted at a given depth into a center portion of the platen 26 through a sidewall of the chamber 10 and the platen 26.

One defect that frequently occurs during the performance of multiple processes of this conventional CVD equipment is that the first and second heating plates 30, 32 become damaged. An amount of damage to the first and second heating plates 30, 32 increases according to the number of processes, i.e., as the number of processes increases, the amount of damage to the first and second heating plates 30, 32 increases. This damage is generally caused by a defective connection between the first and second terminal sockets 34a, 34b, which connect the external power source to the first and second heating plates 30, 32. This defective connection results in a defective process and increases an expense of maintaining the equipment because the defect necessitates changing the first and second heating plates 30, 32, which are expensive, to correct the defective process. In addition, there is a decrease in an operating ratio and a productivity of the equipment. Further, a film forms on a portion of the equipment that is connected to the first and second terminal sockets 34a, 34b. The film has an electrical resistance and is caused by a F⁻ gas, which is used in a periodic cleaning procedure performed by converting NF₃ gas into a plasma state. Consequently, the terminal sockets 34a, 34b, the first and second electrode rods 36a, 36b, and the first and second heating plates 30, 32, melt due to a temperature increase caused by the resistance due to the film.

Moreover, the platen 26 is made of a graphite material, and thus has a defect based on an abnormal growth on the surface thereof during a performance of continuous processes. This defect, which may occur in a cucumber shape, i.e., a cylindrical shape having tapered end portions, gradually increases after a wet cleaning. This abnormal growth of a defect, such as the cucumber shape defect, contaminates a lower surface of the wafer W. Further, the contaminated wafer W pollutes a buffer section having a robot chuck or a robot, or a loadlock part (not shown), in which a loading and unloading of the wafer W is performed during a transfer procedure. Additionally, in a procedure of mounting the wafer W in a cassette, the pollution may react with particles on the lower surface of the wafer W.

FIG. 4 illustrates a sectional view of a second conventional CVD processing equipment.

In the second conventional CVD equipment shown in FIG. 4, a chamber 50, in which a CVD process is performed, includes a showerhead 12, which is provided on an upper portion of the chamber 50, for supplying a gaseous raw material. An exhaust line 52 is provided through a sidewall of the chamber 50 to guide and exhaust the gaseous raw material supplied by the showerhead 12.

A heater block 54 is installed within the chamber 50. The heater block 54 contacts a lower surface of a wafer W, thereby supporting the wafer W, so that the gaseous raw material supplied by the showerhead 12 may contact the wafer W. In operation, the heater block 54 heats the wafer W by selectively generating heat from a first and second heating plate 64, 66, which are provided in an interior of the heater block 54. The heater block 54 includes a body 56 that may be integrally formed with a pipe shaped support shaft 56a, which extends through a lower central portion of the chamber 50. The heater block further includes a sealing member 58 positioned on an edge portion on the body 56 and a platen 60 installed on an upper side of the sealing member 58 to contact a lower surface of the wafer W, thereby supporting the wafer W. A support body 62 is provided between the body 56 and the platen 60, and is supported by the body 56. The first heating plate 64 having a flat surface and the second heating plate 66 having a ring shape are provided on the support body 62 so that a gap is maintained between the first heating plate 64 and the second heating plate 66. An electrical wire 68 for electrically connecting a power source to the first and second heating plates 64, 66 enters a lower side of the chamber 50 through the support shaft 56a.

A purge gas supply line 72 is connected to the support shaft 56a for preventing an influx of the gaseous raw material into the interior of the heater block 54. A thermocouple 70 for detecting a temperature of the first and second heating plates 64, 66 is additionally connected to the support shaft 56a.

The heater bock 54 further includes a lift part 74 for raising and lowering the wafer W. In the lift part 74, at least three lift pins 76 are installed to raise and lower the wafer W. The lift pins 76 extend through the body 56, the support body 62 and the platen 60 from a lower side of the body 56 and avoid contacting the first and second heating plates 64, 66 of the heater block 54. The lift pins 76 contact a lower surface of the wafer W to support the wafer W so that an upper portion of each of the lift pins 76 projects through an upper surface of the heater block 54 to a predetermined height. The projection of the lift pins 76 is controlled by selectively driving a cylinder 80 installed in a lower portion of the heater block 54.

In the second conventional CVD equipment, the electrical wire 68 for connecting the power source to the first and second heating plates 64, 66 extends toward a lower side of the chamber 56 through the support shaft 56a to reduce damage to the connection. However, the support shaft 56a extends through a lower center of the chamber 50, and the exhaust line 52 is connected through a sidewall of the chamber 50. Such a connection of the exhaust line 52 shifts a weight distribution of the equipment away from a center of the chamber 50 toward the exhaust line 52. This shift in weight distribution causes the gaseous raw material supplied into the interior of the chamber 50 to form an air stream directed to a portion of the chamber 50 where the exhaust line 52 is connected. This uneven flow of gaseous raw material causes a process defect in that a thickness of a material layer deposited on the surface of the wafer W is formed unevenly. To prevent such a deviation of gaseous raw material in the above-described second conventional configuration, a connection portion of the exhaust line 52 should be adequately spaced apart from a lower portion of the heater block 54. Such positioning, however, causes a size of the chamber 50 to be enlarged, which necessitates an increase in an amount of gaseous raw material supplied to the chamber 50, thus lowering productivity.

Though an influx of gaseous raw material into the interior of the heater block 54 may be substantially prevented by the purge gas supply line 72, there is still a possibility that some purge gas may flow out from the interior to an upper part of the heater block 54 at a location where the lift pins 76 extend through the platen 60, which adversely affects the CVD process. Further, there is a possibility of damage to the first and second heating plates 64, 66 due to the influx of gaseous raw material through the locations where the lift pins 76 extend through the platen 60.

### SUMMARY OF THE INVENTION

The present invention is therefore directed to chemical vapor deposition (CVD) processing equipment having an improved structure, which substantially overcomes one or more of the problems due to the limitations and disadvantages of the related art.

It is therefore a feature of an embodiment of the present invention to provide CVD processing equipment for use in fabricating a semiconductor device, in which a downward air stream of raw material supplied into an interior of a chamber is uniformly provided over an entire surface of a wafer. It is another feature of an embodiment of the present invention to provide CVD processing equipment for use in fabricating a semiconductor device including a connection portion for electrically connecting an external power source to heating plates provided within a heater block.

At least one of the above features and other advantages may be provided by a CVD processing equipment for use in fabricating a semiconductor device including a chamber having an exhaust line in a lower central portion thereof, a heater block for supporting a wafer to be supplied in an interior of the chamber, the heater block having a heating plate in an interior thereof, a support shaft for supporting the heater block, the support shaft extending through a bottom of the chamber, and an electrical wire for providing an electrical connection to the heating plate, the electrical wire extending through the bottom of the chamber within the support shaft.

The heater block may have a flat surface. The support shaft may have a pipe shape.

The support shaft may include at least two support shafts and the at least two support shafts may be positioned equidistant from the exhaust line at the lower central portion of the chamber.

The heating plate may include a first heating plate having a circular flat surface and being installed in a central portion of the heater block and a second heating plate having a ring shape, the second heating plate surrounding the first heating plate with a predetermined gap therebetween.

The electrical wire may be a plurality of electrical wires, a first electrical wire being electrically connected to the first heating plate and extending through one of the at least two support shafts and a second electrical wire being electrically connected to the second heating plate and extended through another of the at least two support shafts.

The support shaft may include a lower portion extending through the bottom of the chamber and an upper portion, which is supported by the bottom of the chamber, for contacting and supporting the heater block. The upper portion of the support shaft may have a larger cross-section than the lower portion.

The heater block may include a body supported by the support shaft; a sealing member having a ring shape on an upper edge of the body; and a platen having a flat surface on the sealing member, wherein an upper surface of the platen contacts a lower surface of the wafer and an edge portion of the platen extends beyond the wafer and contacts a side part of the body to form the interior of the heater block, the interior of the heater block being sealed.

The body and the support shaft may be integrally formed.

The heater block may be formed of a ceramic material.

The CVD processing equipment may further include a lift part positioned within the chamber for raising and lowering the wafer, the lift part including a cylinder supported by the bottom of the chamber, a lift pin operable to be raised or lowered by the cylinder, and a wafer support for contacting the wafer, the wafer support being supported by the lift pin. The lift pin may be disposed beyond an edge of the heater block.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 illustrates a partial cut-away view of a first conventional chemical vapor deposition processing equipment;

FIG. 2 illustrates a sectional view of the first conventional chemical vapor deposition processing equipment shown in FIG. 1 including a heater block;

FIG. 3 illustrates an enlarged view of a region “III” of FIG. 2 showing a connection of a heater block to an external power source;

FIG. 4 illustrates a sectional view of a second conventional chemical vapor deposition processing equipment; and

FIG. 5 illustrates a sectional view of a chemical vapor deposition processing equipment according to an exemplary embodiment of the present invention.

### DETAILED DESCRIPTION OF THE INVENTION

Korean Patent Application No. 2003-52178, filed on Jul. 29, 2003, in the Korean Intellectual Property Office, and entitled: “Chemical Vapor Deposition Processing Equipment for Use in Fabricating a Semiconductor Device,” is incorporated by reference herein in its entirety.

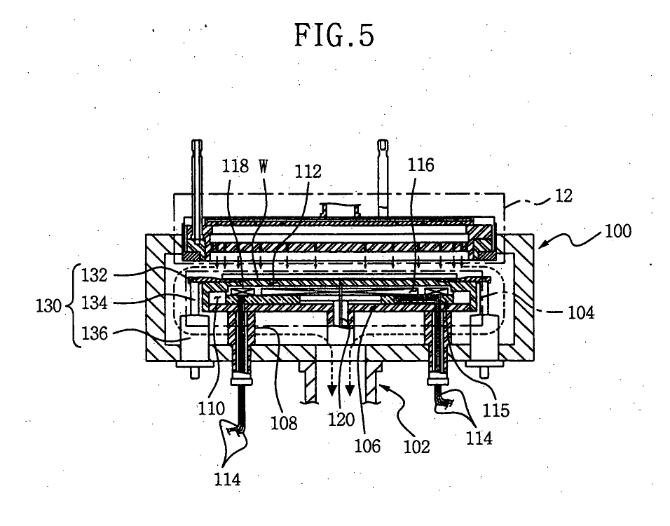

The present invention will now be described more fully hereinafter with reference to FIG. 5, in which an exemplary embodiment of the invention is shown. The invention may, however, be embodied in different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

FIG. 5 illustrates a sectional view of chemical vapor deposition (CVD) processing equipment for use in fabricating a semiconductor device according to an exemplary embodiment of the present invention.

According to an exemplary embodiment of the present invention and referring to FIG. 5, CVD processing equipment for use in fabricating a semiconductor device includes a chamber 100 having a showerhead 12 for supplying a gaseous raw material into an upper portion of the chamber 100, and an exhaust line 102 for discharging air and the supplied gaseous raw material from an interior of the chamber 100 using a downward air stream. The exhaust line 102 is formed in a lower central portion of the chamber 100.

The chamber 100 further includes at least two pipe shaped support shafts 108 positioned along a circumference of a portion connected to the exhaust line 102. The at least two support shafts 108 are supported by and extend through a bottom of the chamber 100. The support shafts 108 may be desirably positioned equidistant from a center of the bottom of the chamber 100 where the exhaust line 102 connection is provided. Each support shaft 108 may include a lower portion and an upper portion. The lower portion of each support shaft is inserted into and extends through the bottom of the chamber 100 and may be raised or lowered through the bottom of the chamber 100. The upper portion of each of the support shafts 108 may have a relatively larger cross-sectional size than the lower portion, e.g., may extend farther out in a side direction, so that the upper portion of each support shaft 108 may contact and be supported by the bottom of the chamber 100 at a location adjacent to where the lower portion of the support shaft 108 extends through the bottom of the chamber 100.

A heater block 104 contacts and is supported by the upper portion of each of the support shafts 108. The heater block 104 includes a heating plate, which may be a first and a second heating plate 116, 118, in an interior thereof. In an embodiment of the present invention, a lower part of the heater block 104, i.e., a body 106, and the upper portion of each of the support shafts 108 may be integrally formed and have a shape extended and projected toward a lower side of the chamber 100.

The heater block 104 will now be described in greater detail. The heater block 104 includes a body 106 having a flat surface. A gap is maintained between the body 106 and the bottom of the chamber 100 by the support shafts 108. A sealing member 110, or a gap retaining part, having a ring shape of a predetermined thickness is positioned on an upper surface of the body 106 at an edge portion thereof. A platen 112 is positioned on the sealing member 110 or the gap retaining part. The platen 112 has a flat surface formed of a ceramic material and contacts a lower surface of a wafer W, thereby supporting the wafer W. The platen 112 has a shape in which an edge portion thereof covers a sidewall of the body 106. The body 106, the platen 112 and the sealing member 110 or the gap retaining part provided therebetween are attached together using a general fastener (not shown) to maintain a sealing state between the interior and the exterior of the heater block 104.

A support body 115 formed of a quartz material having a predetermined thickness is positioned on a bottom portion of the body 106 between the body 106 and the platen 112. The first and second heating plates 116, 118 are positioned on the support body 115. The first heating plate 116 having a circular flat surface is positioned in a central portion of the heater block 104, e.g., concentric with a center of the heater block 104. Accordingly, a center of the wafer W placed at a predetermined position on the heater block 104 may be concentric with the first heating plate 116 and the heater block 104. The second heating plate 118 having the ring shape is positioned a predetermined distance from the first heating plate 116 to surround the first heating plate 116 with a gap therebetween.

To electrically connect a power source to the first and second heating plates 116, 118, electrical wires 114 connected to first and second heating plates 116, 118 extended through the bottom of the chamber 100 within the support shaft 108 and are electrically connected to an external power source supply part (not shown). In an embodiment of the present invention where the heating plate is divided into at least two heating plates 116, 118, the electrical wires 114 connected to each of the heating plates extend through the bottom of the chamber 100 within the support shafts 108. More specifically, a first electrical wire may be electrically connected to the first heating plate and extend through one of the support shafts and a second electrical wire may be electrically connected to the second heating plate and extended through another of the support shafts.

A purge gas supply line may be connected to any one of the support shafts 108 to supply a purge gas to prevent an inflow of gaseous raw material into the interior of the heater block 104. A thermocouple 120 may be inserted through any one of the support shafts 108 to check a generation heat level of the first and second heating plates 116, 118, i.e., a temperature of the platen 112.

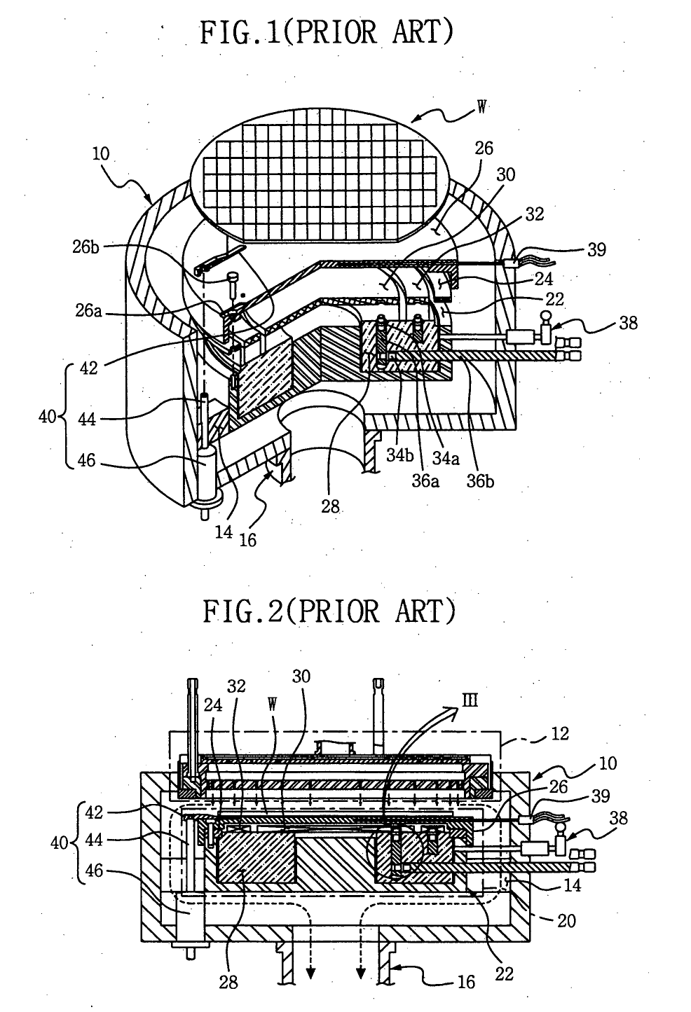

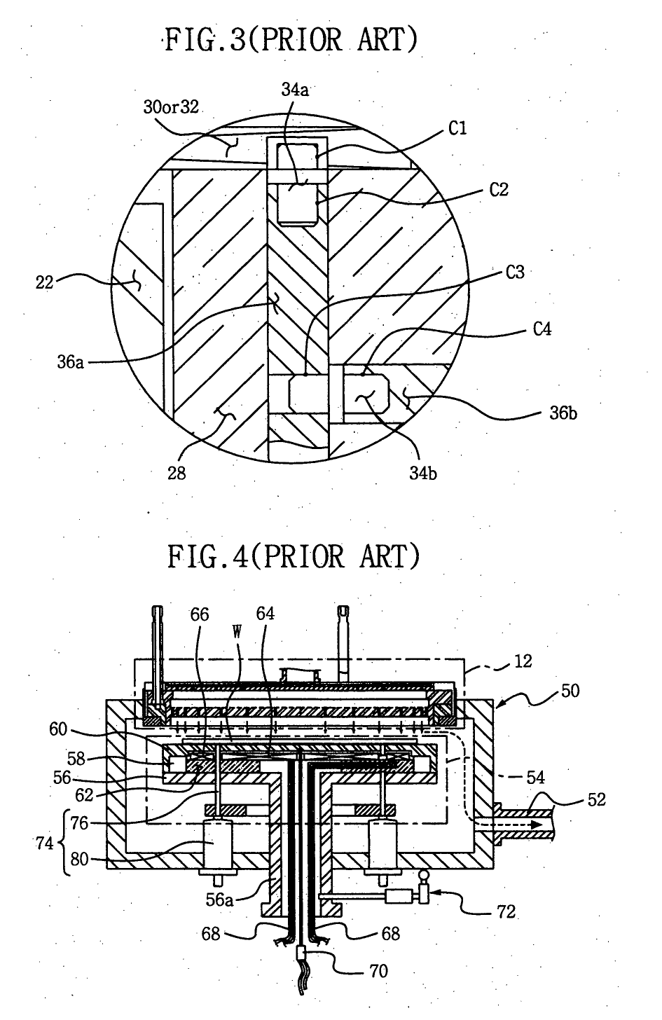

A lift part 130 for raising and lowering the wafer W, which is supported by the platen 112, is positioned to a side part of the heater block 104. The lift part 130 includes a cylinder 136 supported by a bottom of the chamber 100, a lift pin 134, which is raised or lowered by driving the cylinder 136, and a wafer support 132 that is supported by the lift pin 134. The wafer support 132 has a shape corresponding to a flute formed on the platen 112, similar to the configuration of the lift part 40 shown in FIG. 1 or 2, although in the present invention, the lift pin 134 is disposed beyond an edge of the platen 112 to avoid extending through the platen 112 or penetrating the interior of the sealed heater block 104.

CVD processing equipment according to an embodiment of the present invention provides the following several advantages. First, a connection of an external power source to a heating plate provided within a heater block may be more stably provided by connecting an electrical wire extended from the heating plate to the external power source supply part through a support shaft. Second, respective components may be combined with one another in a simplified structure, thereby reducing a size of the chamber. Third, the structure of the present invention facilitates assembling and disassembling the equipment, thereby reducing inconvenience and cost of repair work when such repair work becomes necessary. Fourth, the structure of the present invention reduces damage to the heating plate.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A chemical vapor deposition (CVD) processing equipment for use in fabricating a semiconductor device, comprising:
a chamber having an exhaust line in a lower central portion thereof;
a heater block for supporting a wafer to be supplied in an interior of the chamber, the heater block having a heating plate in an interior thereof;
a support shaft for supporting the heater block, the support shaft extending through a bottom of the chamber; and
an electrical wire for providing an electrical connection to the heating plate, the electrical wire extending through the bottom of the chamber within the support shaft.

2. The equipment as claimed in claim 1, wherein the heater block has a flat surface.

3. The equipment as claimed in claim 1, wherein the support shaft has a pipe shape.

4. The equipment as claimed in claim 1, wherein the support shaft comprises at least two support shafts, the at least two support shafts being positioned equidistant from the exhaust line at the lower central portion of the chamber.

5. The equipment as claimed in claim 4, wherein the heating plate comprises:
a first heating plate having a circular flat surface and being installed in a central portion of the heater block; and
a second heating plate having a ring shape, the second heating plate surrounding the first heating plate with a predetermined gap therebetween.

6. The equipment as claimed in claim 5, wherein the electrical wire is a plurality of electrical wires, a first electrical wire being electrically connected to the first heating plate and extending through one of the at least two support shafts and a second electrical wire being electrically connected to the second heating plate and extended through another of the at least two support shafts.

7. The equipment as claimed in claim 1, wherein the support shaft comprises:
a lower portion extending through the bottom of the chamber; and
an upper portion, which is supported by the bottom of the chamber, for contacting and supporting the heater block.

8. The equipment as claimed in claim 7, wherein the upper portion of the support shaft has a larger cross-section than the lower portion.

9. The equipment as claimed in claim 1, wherein the heater block comprises:
a body supported by the support shaft;
a sealing member having a ring shape on an upper edge of the body; and
a platen having a flat surface on the sealing member, wherein an upper surface of the platen contacts a lower surface of the wafer and an edge portion of the platen extends beyond the wafer and contacts a side part of the body to form the interior of the heater block, the interior of the heater block being sealed.

10. The equipment as claimed in claim 9, wherein the body and the support shaft are integrally formed.

11. The equipment as claimed in claim 9, wherein the heater block is formed of a ceramic material.

12. The equipment as claimed in claim 1, further comprising a lift part positioned within the chamber for raising and lowering the wafer, the lift part including:
a cylinder supported by the bottom of the chamber;
a lift pin operable to be raised or lowered by the cylinder; and
a wafer support for contacting the wafer, the wafer support being supported by the lift pin.

13. The equipment as claimed in claim 12, wherein the lift pin is disposed beyond an edge of the heater block.
